(19) United States
(12) Patent Application Publication
(10) Pub. No.: US 2026/0181950 A1
(43) Pub. Date: Jun. 25, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Chien-Lin YU, Miaoli County (TW); Zhi-Chang LIN, Hsinchu County (TW); Kuan-Kan HU, Hsinchu (TW); Tsung-Kai CHIU, Hsinchu County (TW); James June Fan HSU, New Taipei City (TW)

(73) Assignee: TAIWAN SEMICONDUCTOR MANUFACTURING COMPANY, LTD., Hsinchu (TW)

(21) Appl. No.: 18/990,066

(22) Filed: Dec. 20, 2024

(51) Int. Cl. H10D 30/67; H10D 62/10; H10D 62/13; H10D 64/01; H10D 84/01; H10D 84/85

(52) U.S. Cl. CPC H10D 30/6735; H10D 30/6757; H10D 62/118; H10D 62/151; H10D 64/021; H10D 84/017; H10D 84/85

(57) ABSTRACT

A method includes the following steps. A first plurality of semiconductor nanostructures is formed over a substrate. A second plurality of semiconductor nanostructures is formed over the first plurality of semiconductor nanostructures. First source/drain regions are formed connected by the first plurality of semiconductor nanostructures. Second source/drain regions are formed connected by the second plurality of semiconductor nanostructures. First inner spacers are formed interposing the first plurality of semiconductor nanostructures. Second inner spacers are formed interposing the second plurality of semiconductor nanostructures. A gate structure is formed surrounding the first plurality of semiconductor nanostructures and the second plurality of semiconductor nanostructures, the gate structure being spaced apart from the first source/drain regions by the first inner spacers, and spaced apart from the second source/drain regions by the second inner spacers. Each first inner spacer has a width different from a width of each second inner spacer.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure.

FIGS. 2A to 12 illustrate a method in various stages of forming a semiconductor device in accordance with some embodiments of the present disclosure.

FIGS. 13 to 22 illustrate a method in various stages of forming a semiconductor device in accordance with some embodiments of the present disclosure.

FIGS. 23 and 24 illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

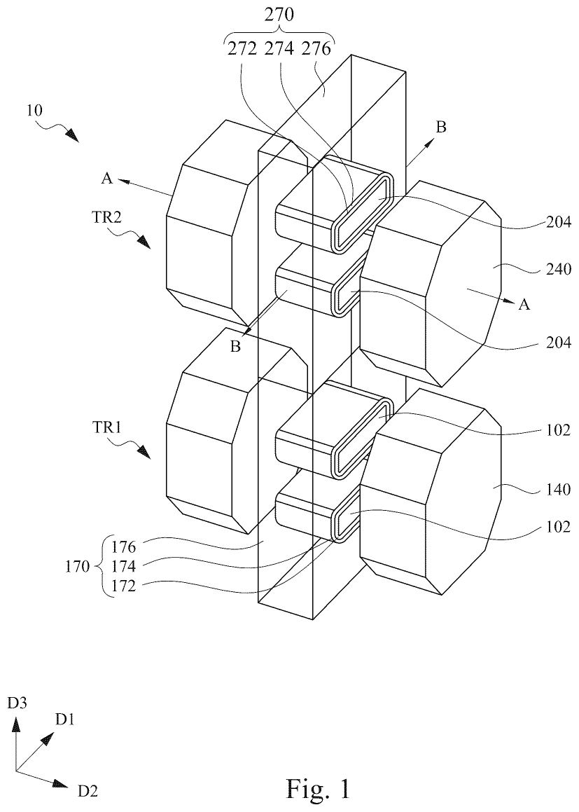

FIG. 1 is a perspective view of a semiconductor device in accordance with some embodiments of the present disclosure. In the present disclosure, a complementary FET (CFET) 10 is provided, and its manufacturing method will be disclosed in the following discussion. In a CFET 10, a first transistor TR1 is disposed over a substrate (not shown), and a second transistor TR2 is disposed vertically above the first transistor TR1. In some embodiments, the first transistor TR1 and the second transistor TR2 may be field effect transistor (FET) and may both include gate-all-around (GAA) configuration, and thus the first transistor TR1 and the second transistor TR2 can also be referred to as GAA FET. The first transistor TR1 includes semiconductor layers 102 vertically stacked one above another, a first metal gate structure 170 wrapping around each of the semiconductor layers 102, and first source/drain epitaxy structures 148 on opposite ends of each of the semiconductor layers 102. Similarly, the second transistor TR2 includes semiconductor layers 204 vertically stacked one above another, a second metal gate structure 270 wrapping around each of the semiconductor layers 204, and second source/drain epitaxy structures 240 on opposite ends of each of the semiconductor layers 204. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276. In some embodiments, the first transistor TR1 has a first conductivity type (e.g., n-type) and the second transistor TR2 has a second conductivity type (e.g., p-type) different from the first conductivity type. In some embodiments, the first transistor TR1 can be referred to as an N-FET, and the second transistor TR2 can be referred to as a P-FET. In some embodiments, the semiconductor layers 102 may include material suitable for N-type device, such as silicon (Si), while the semiconductor layers 204 may include material suitable for P-type device, such as silicon germanium (SiGe).

Source/drain recesses where the first source/drain epitaxy structures 148 and the second source/drain epitaxy structures 240 may be deposited may be formed by etching portions of the substrate 100 and portions of an initial semiconductor stack. In an etching step to the formation of the source/drain recesses, the first metal gate structure 170 and the second metal gate structure 270 may include the same gate length with the same polysilicon (poly) critical dimension (CD) and the same poly spacer thickness. However, n-type channel and p-type channel may thus share the same gate length, leading to increased difficulty to achieve diverse top and bottom gate lengths to enable the flexibility of the device architecture.

The present disclosure provides a method of forming complementary FET with a top gate length different from a bottom gate length, thus enabling the flexibility of the device architecture.

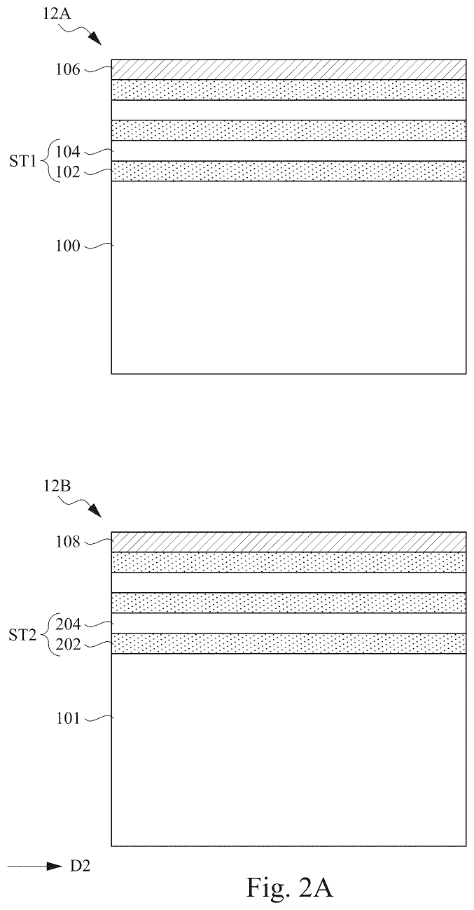

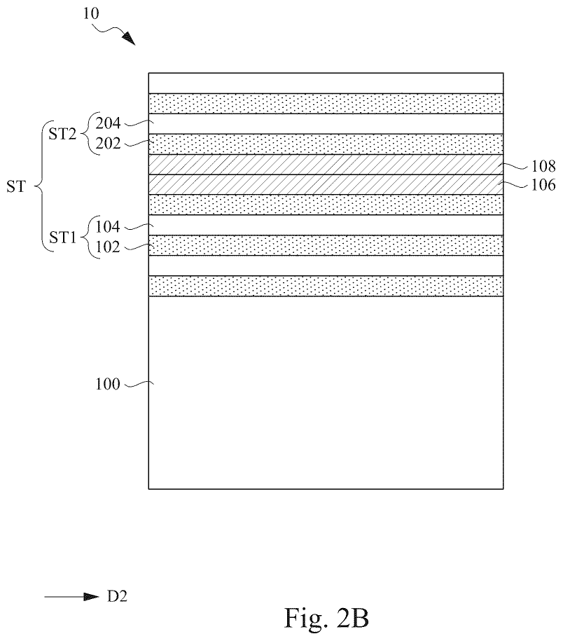

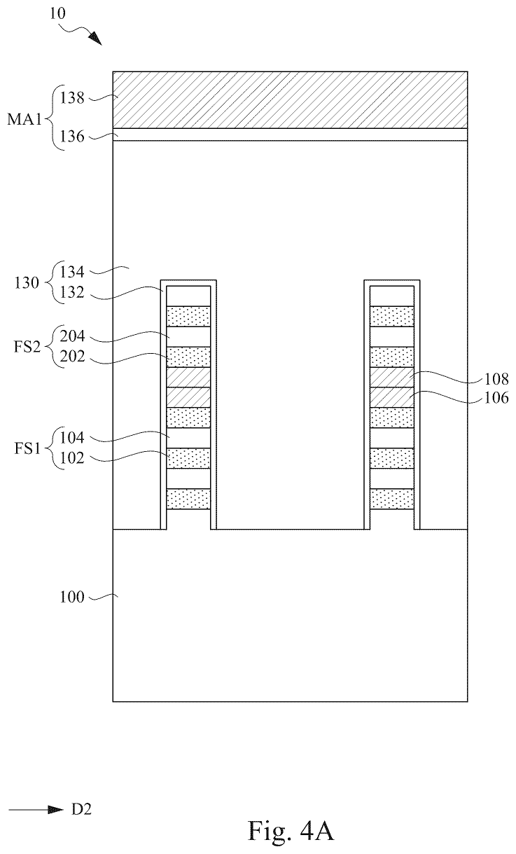

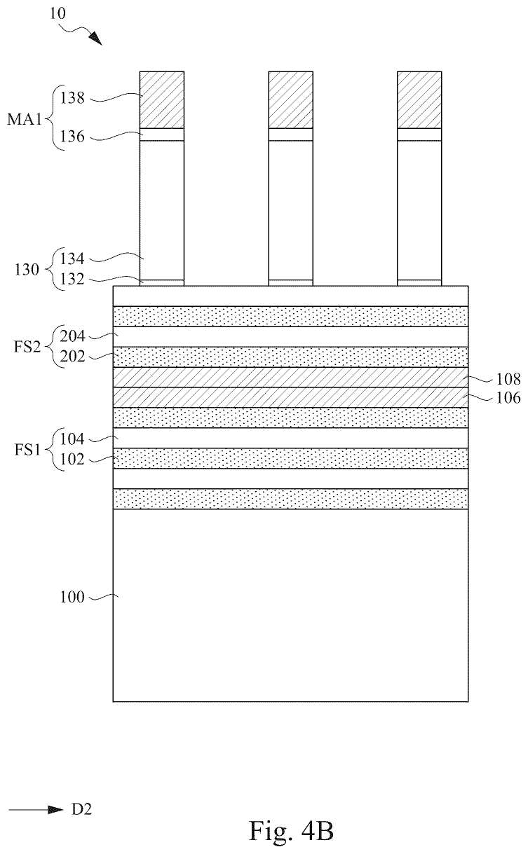

FIGS. 2A to 12 illustrate a method in various stages of forming a semiconductor device in accordance with some embodiments of the present disclosure. In greater detail, FIGS. 2A to 12 illustrate a method for forming a detailed structure of the CFET 10 of FIG. 1. It is noted that FIGS. 2A, 2B, 3 and 4A include cross-sectional views the same as the cross-sectional view along line A-A of FIG. 1, and FIGS. 4B, 5, 6, 7, 8, 9, 10, 11 and 12 include cross-sectional views the same as the cross-sectional view along line B-B of FIG. 1. Line B-B extends along a first direction D1. Line A-A extends along a second direction D2. A third direction D3 extends along a vertical direction perpendicular to the first direction D1 and the second direction D2. Although FIGS. 2A to 12 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2A to 12 may be similar to those described with respect to FIG. 1, and thus relevant details will not be repeated for brevity. Referring to FIG. 2A, a first device of a stacked device structure, such as a device 12A of the CFET 10 can be formed, and a second device include a device 12B of the CFET 10 can be formed.

The device 12A may include a substrate 100 and a first stack ST1 of alternating semiconductor layers 102 and 104 and a first insulation layer 106 over the first stack ST1. The substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

The device 12B may include a substrate 101 and a second stack ST2 of alternating semiconductor layers 202 and 204 and a second insulation layer 108 over the second stack ST2. The substrate 101 may include similar material as the substrate 100, and thus the description thereof is omitted herein. In some embodiments, the semiconductor layers 102 and 202 may be made of pure silicon layers that are free of germanium. The semiconductor layers 102 and 202 may also be substantially pure silicon layers. The semiconductor layers 104 and 204 may be made of silicon germanium. In some embodiments, the semiconductor layers 102, 104, 202, and 204 may be deposited using suitable deposition process, such as selective epitaxial growth (SEG), chemical vapor deposition (CVD), molecular beam epitaxy (MBE), or other suitable process(es).

In FIG. 2B, a frontside of the device 12A is bonded and/or attached to a backside of the device 12B by the first insulation layer 106 and the second insulation layer 108 (also referred to as bonding layers). In some embodiments, the device 12A is bonded to the device 12B using dielectric-to-dielectric bonding. For example, bonding includes forming flipping over and placing the device 12B over the device 12A, such that first insulation layer 106 contacts the second insulation layer 108, and performing an annealing process or other suitable process to effectuate bonding of first insulation layer 106 and the second insulation layer 108. In some embodiments, the dielectric-to-dielectric bonding process is an oxide-to-oxide bonding process in which the first insulation layer 106 and the second insulation layer 108 are oxide layers.

After bonding, a thinning process and/or a de-bonding process may be performed to remove the substrate 101 from the device 12B. For example, a planarization process, such as CMP, or an etching process can be performed to remove the substrate 101. A top layer of the semiconductor layers 202 may function as a CMP stop layer and/or an etch stop layer when removing the substrate 101. Thereafter, the top layer of the semiconductor layers 202 may be removed from the second stack ST2, for example, by an etching process. Removing the top layer of the semiconductor layers 202 provides the device 12B with a top layer of the semiconductor layers 204, which will provide a top channel of the device 12B as described herein. Other methods and/or techniques for removing the substrate 101 and/or the top layer of the semiconductor layers 202 are contemplated.

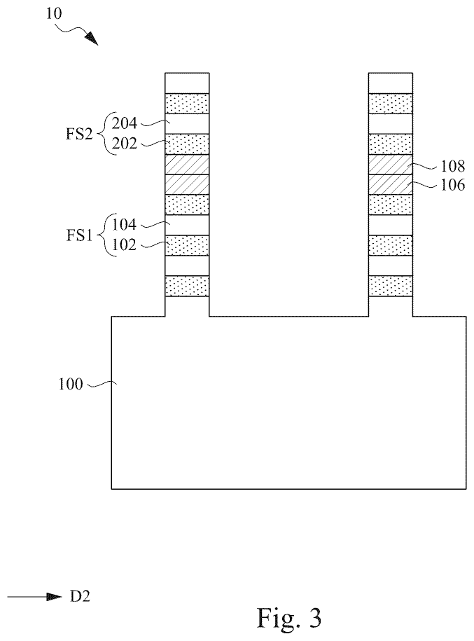

A patterning process may be performed to the second stack ST2 and the first stack ST1 to form a second fin structure FS2 and a first fin structure FS1, respectively, as shown in FIG. 3. In some embodiments, the patterning process may include forming a patterned photoresist layer over the stack ST, and then performing an etching process to remove unwanted portions of the second stack ST2 and the first stack ST1 exposed by the patterned photoresist layer. The second fin structure FS2 may include a remaining portion of the second stack ST2 protruding over the second insulation layer 108. The first fin structure FS1 may include a remaining portion of the first stack ST1 protruding over the substrate 100. In some embodiments, the etching process may include wet etch, dry etch, or the like.

Reference is made to FIGS. 4A and 4B. Dummy gate structures 130 are formed over and crossing the second fin structure FS2, the second insulation layer 108, the first insulation layer 106 and the first fin structure FS1. In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the second fin structure FS2 and the second insulation layer 108, forming patterned masks MA1 over the dummy gate layer, and then performing an etching process to the dummy dielectric layer and the dummy gate layer by using the patterned masks MA1 as etch mask. In some embodiments, the dummy gate layer may be deposited by physical vapor deposition (PVD), chemical vapor deposition (CVD), sputter deposition, or other techniques for depositing the selected material. In some embodiments, the dummy dielectric layer may be formed by thermal oxidation.

In some embodiments, each of the patterned masks MA1 includes a first hard mask 136 and a second hard mask 138 over the first hard mask 136. The first hard mask 136 and the second hard mask 138 may be made of different materials. In some embodiments, the second hard mask 138 may be formed of silicon nitride, and the first hard mask 332 may be formed of silicon oxide.

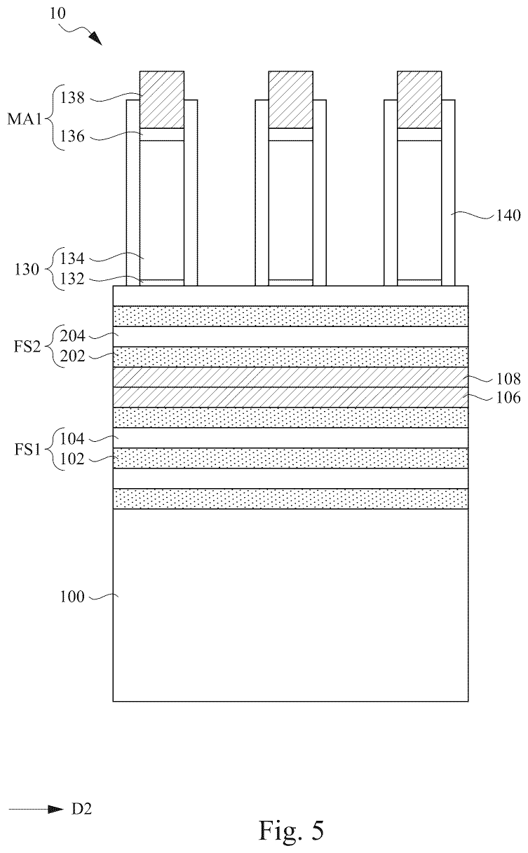

Reference is made to FIG. 5. Gate spacers 140 are formed on opposite sidewalls of each of the dummy gate structures 130. In some embodiments, the gate spacers 140 may be formed of silicon oxide, silicon nitride, silicon oxynitride, combinations thereof. In some embodiments, the gate spacers 140 may be formed by, for example, depositing a spacer layer blanket over the second fin structure FS2, and then performing an anisotropic etching process to remove horizontal portions of the spacer layer, such that vertical portions of the spacer layer remain on sidewalls of the dummy gate structures 130. In some embodiments, the remaining vertical portions of the spacer layer on sidewalls of the dummy gate structures 130 can be referred to as gate spacers 140. In some embodiments, the spacer layer may be deposited using techniques such CVD, atomic layer deposition (ALD), or the like.

After the gate spacers 140 are formed, an etching process is performed, by using the gate spacers 140 and the patterned masks MA1 (or the dummy gate structures 130) as etch mask, to remove portions of the second fin structure FS2. The resulting structure is shown in FIG. 6. In greater detail, the etching process removes portions of the semiconductor layers 202 and 204, so as to form recesses R1 in the second fin structure FS2. In some embodiments, the second insulation layer 108 may include higher etch resistance to the etching process than the semiconductor layers 202 and 204, and thus the second insulation layer 108 may act as an etch stop layer during the etching process. As a result, the etching process may be stopped at the second insulation layer 108, and thus the underlying semiconductor layers 102 and 104 are protected by the second insulation layer 108 and may keep substantially intact after the etching process is complete.

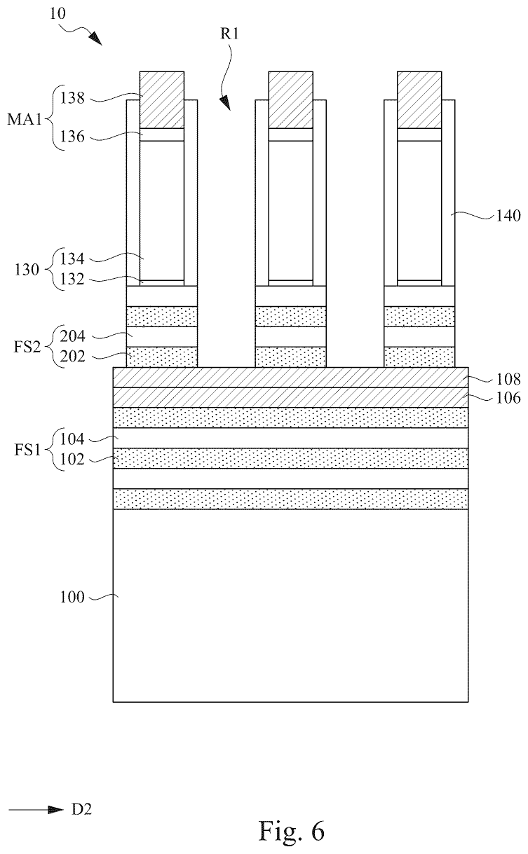

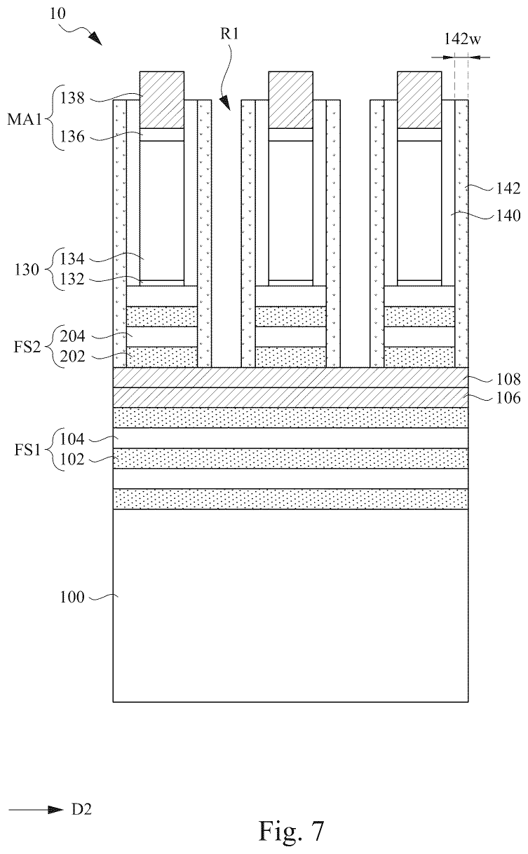

Reference is made to FIG. 7. Liners 142 are formed lining sidewall surfaces of the gate spacers 140 and sidewall surfaces of the second fin structure FS2. In some embodiments, the liners 142 may be formed by, for example, depositing a liner layer blanket over the second insulation layer 108, the patterned masks MA1, the gate spacers 140 and the second fin structure FS2, an anisotropic etching process is performed to remove horizontal portions of the liner layer, such that vertical portions of the liner layer remain on sidewalls of the gate spacers 140 and the sidewall surfaces of the second fin structure FS2. In some embodiments, the remaining vertical portions can be referred to as the liners 142. In some embodiments, the liners 142 may be made of SiN, metal oxide, or other suitable material. In some embodiments, bottommost ends of the liners 142 may be substantially level with a bottom surface of the semiconductor layer 202. In some embodiments, the liners 142 can include a width 142w along the first direction D1.

Reference is made to FIG. 8. An etching process is performed, by using the liners 142, the gate spacers 140, the patterned masks MA1 (or the dummy gate structures 130) and the second fin structure FS2 as etch mask, to remove portions of the first fin structure FS1. In greater detail, the etching process removes a portion of the second insulation layer 108, a portion of the first insulation layer 106 and portions of the semiconductor layers 102 and 104, so as to form recesses R2 in the first fin structure FS1, and in the substrate 100. In some embodiments, the liners 142 may protect the semiconductor layers 202 and 204 during the etching process, and thus the semiconductor layers 202 and 204 may keep substantially intact after the etching process is complete. In some embodiments, the exposed portions of the substrate 100 may be slightly etched during the etching process, and thus the bottom surfaces of the recesses R2 may be lower than top surface of the substrate 100. In some embodiments, the etching process may be wet etch, dry etch, or combinations thereof. In some embodiments, the recess R2 is narrower than the recess R1. That is, the first fin structure FS1 can be wider. By controlling the width 142w of the liners 142 extending along the first direction D1, a width w1 of the first fin structure FS1 extending along the first direction D1 can be tuned. Therefore, a thickness of a subsequently formed bottom gate stack can be tuned. For example, as the liners 142 include increased width 142w, the first fin structure FS1 can include increased width w1, resulting in increased gate length of the subsequently formed bottom gate stack. Due to the presence of the liners 142, in some embodiments, the second fin structure FS2 can include a width w2 smaller than a width w1 of the first fin structure FS1 along the first direction D1. Therefore, the diversity between top gate length and bottom gate length can be controlled and thus enables the flexibility of the device architecture.

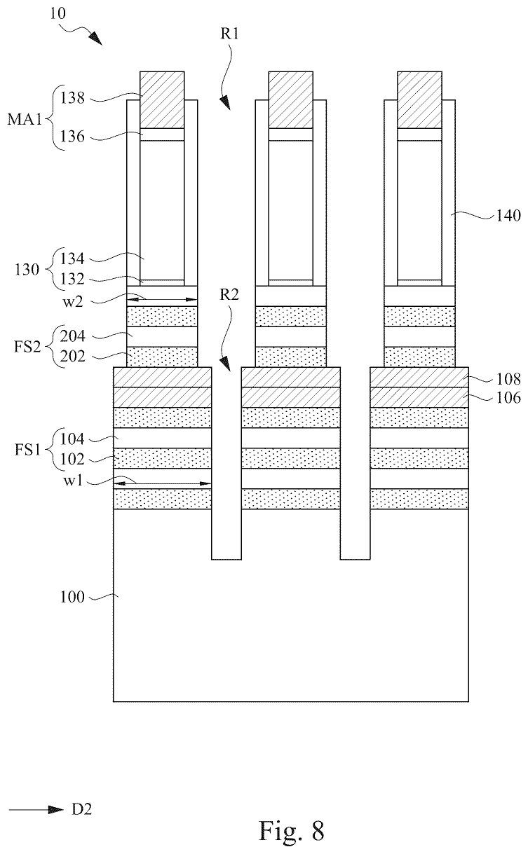

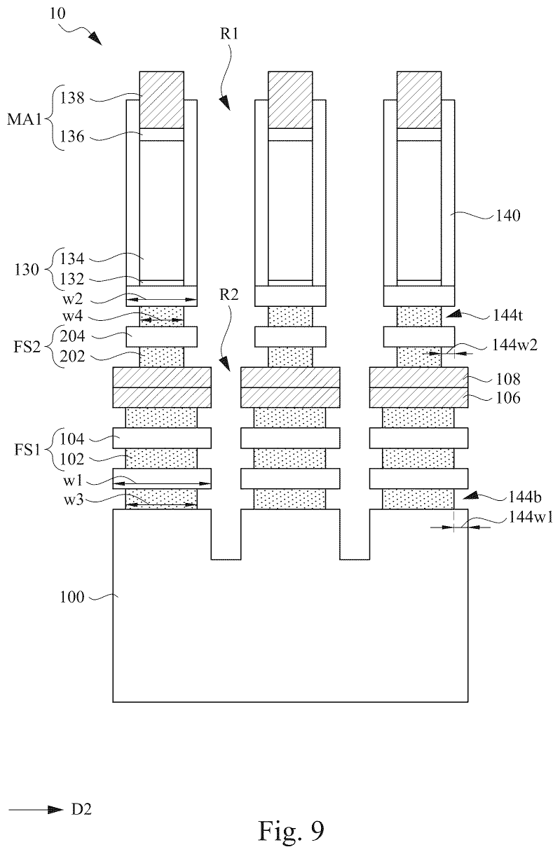

Reference is made to FIG. 9. The semiconductor layers 102 and 202 are laterally etched to form sidewall recesses 144b, 144t. Although sidewalls of the semiconductor layers 102 in the sidewall recesses 144b, 144t are illustrated as being straight in FIG. 9, the sidewalls may be concave or convex. The sidewalls may be etched using isotropic etching processes, such as wet etching or the like. In some embodiments in which the semiconductor layers 102 and 202 include, e.g., SiGe, and the semiconductor layers 104, 204 include, e.g., Si or SiC, a dry etch process with tetramethylammonium hydroxide (TMAH), ammonium hydroxide (NH₄OH), or the like may be used to etch sidewalls of the semiconductor layers 102 and 202. In some embodiments, because the sidewall recesses 144b, 144t are formed in the same time point, the sidewall recesses 144b may include a width 144w1 along the first direction D1 substantially the same as a width 144w2 of the sidewall recess 144t along the first direction D1. After formation of the sidewall recesses 144b, 144t, the semiconductor layers 102 can include a width w3 along the first direction D1 greater than a width w4 of the semiconductor layers 202 along the first direction D1.

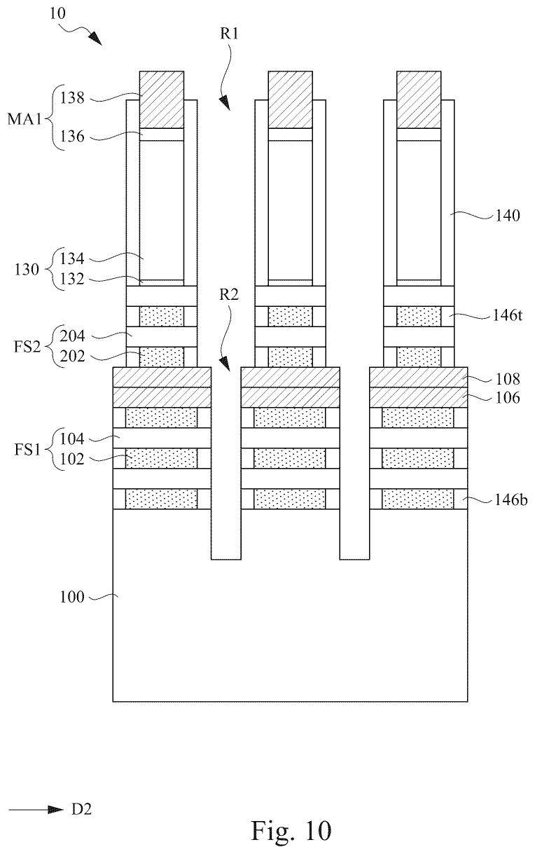

Reference is made to FIG. 10. Then, inner spacers 146 are formed in the sidewall recesses 144b on opposite ends of each of the semiconductor layers 102 and in the sidewall recesses 144t on opposite ends of each of the semiconductor layers 202. In some embodiments, the inner spacers 146 may be formed by, for example, depositing an inner spacer layer blanket over the substrate 100, filling the sidewall recesses 144b on opposite sides of the semiconductor layers 102 and filling the sidewall recesses 144t on opposite sides of the semiconductor layers 202, and then performing an anisotropic etching to remove portions of the inner spacer layer outside the sidewall recesses 144b, 144t, leaving the remaining portions of the inner spacer layer in the sidewall recesses 144b as the inner spacers 146b, and leaving the remaining portions of the inner spacer layer in the sidewall recesses 144t as the inner spacers 146t. The inner spacers 146b, 146t may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized. In some embodiments, because the inner spacers 146b, 146t are formed in the same time point, the inner spacers 146b, 146t may include the same material. In some embodiments, the inner spacers 146b, 146t may include substantially the same widths along the first direction D1.

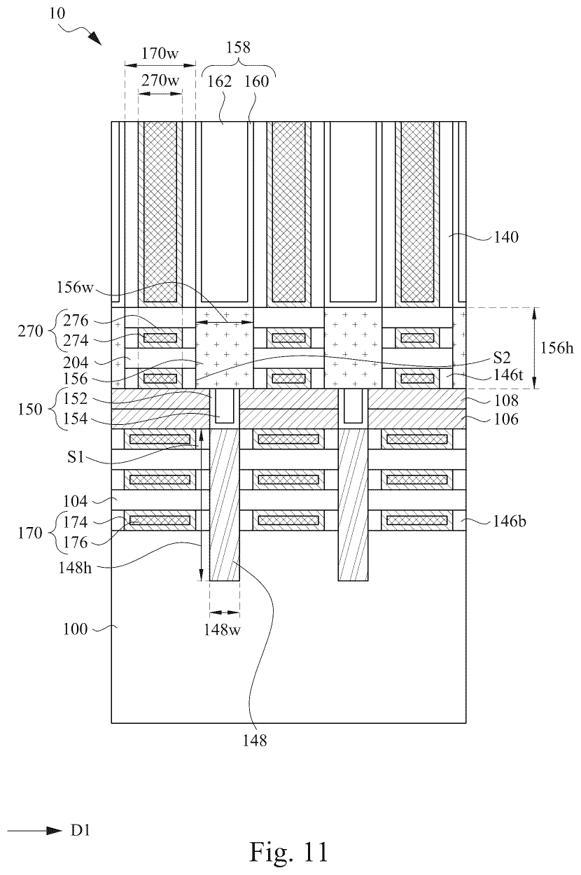

Reference is made to FIG. 11. First source/drain epitaxy structures 148 are formed over the substrate 100 and in contact with opposite ends of the semiconductor layers 104. The first source/drain epitaxy structures 148 may be formed by suitable deposition process, such as CVD, ALD or MBE. During the formation of the first source/drain epitaxy structures 148, the semiconductor layers 202 and 204 may be masked to prevent undesired epitaxial growth on the semiconductor layers 202 and 204. For example, a dielectric layer (not shown) can be formed in the recess R2, and a mask (not shown) can be formed over the dielectric layer and extend along sidewalls of the semiconductor layers 202 and 204 and inner spacers 146t. The dielectric layer can have an etch selectivity to the mask. The dielectric layer may then be removed by a suitable etch process, leaving the mask along the sidewalls of the semiconductor layers 202 and 204. After the first source/drain epitaxy structures 148 are formed, the masks on the sidewalls of semiconductor layers 202 and 204 may then be removed. In some embodiments, the first source/drain epitaxy structures 148 may include SiAs, SiP, or combination of SiAs and SiP. In some embodiments, an implantation process may be performed to the first source/drain epitaxy structures 148. For example, the implantation process may include n-type dopants, such as phosphorus (P), arsenic (As), or antimony (Sb), or the like, such that the first source/drain epitaxy structures 148 are n-type epitaxy structures.

Then, isolation structures 150 are formed over the first source/drain epitaxy structures 148, respectively. A first contact etch stop layer (CESL) 152 and/or a first inter-layer dielectric (ILD) 154 may also be formed in the recesses R2. The first ILD 154 thus acts as isolation regions to prevent shorting of the lower and upper nanostructure-FETs. The first ILD 154 may be formed of a dielectric material, which may be deposited by any suitable method, such as CVD, plasma-enhanced chemical vapor deposition (PECVD), or flowable CVD (FCVD). Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The first CESL 152 may be formed between the first ILD 154 and the first source/drain epitaxy structures 148. The first CESL 152 may be formed of a dielectric material having a high etching selectivity to the dielectric material of the first ILD 154, such as silicon nitride, silicon oxide, silicon oxynitride, or the like, which may be formed by any suitable deposition process, such as CVD, ALD, or the like.

The first CESL 152 and/or the first ILD 154 may be formed by depositing a material for the first CESL 152 and depositing a material for the first ILD 154, followed by a planarization process and then an etch-back process. In some embodiments, the first ILD 154 is initially etched, leaving the first CESL 152 unetched. An anisotropic etching process is then performed to remove the portions of the first CESL 152 that are higher than the first ILD 154. After the recessing, the sidewalls of the semiconductor nanostructures 204 and the gate spacers 140 are exposed.

Second source/drain epitaxy structures 156 are formed on opposite ends of each of the semiconductor layers 204. In some embodiments, the second source/drain epitaxy structures 156 may be formed by a selective epitaxial growth (SEG) process. The SEG process may selectively grow a semiconductor material on exposed semiconductor surfaces, such as the exposed surfaces of the semiconductor layers 204. In some embodiments, the second source/drain epitaxy structures 156 may include SiB, SiGe, or combination of SiB and SiGe. In some embodiments, an implantation process may be performed to the second source/drain epitaxy structures 156. For example, the implantation process may include p-type dopants, such as boron (B), gallium (Ga), indium (In), aluminium (Al), or the like, such that the second source/drain epitaxy structures 156 are p-type epitaxy structures. In some embodiments, each of the inner spacers 146b and one of the first source/drain epitaxy structures 148 have an interface S1 misaligned with an interface S2 between each of the inner spacers 146t and one of the second source/drain epitaxy structures 156. In some embodiments, each of first source/drain epitaxy structures 148 may have a width 148w different from a width 156w of the second source/drain regions 156. In some embodiments, each of the first source/drain epitaxy structures 148 may have the width 148w smaller than the width 156w of the second source/drain regions 156. In some embodiments, each of the first source/drain epitaxy structures 148 may have a height 148h different from a height 156h of the second source/drain regions 156. In some embodiments, each of the first source/drain epitaxy structures 148 may have the height 148h greater than the height 156h of the second source/drain regions 156.

Isolation structures 158 are formed over the second source/drain epitaxy structures 156, respectively. Each of the isolation structures 158 may include a second contact etch stop layer (CESL) 160 and a second interlayer dielectric (ILD) 162 over the second CESL 160. The isolation structures 158 may be formed by, for example, depositing dielectric material(s) over the second source/drain epitaxy structures 156, and then performing a planarization process, such as CMP, to remove excess dielectric material(s). In some embodiments, during the planarization process, the patterned masks MA1 are removed, and the dummy gate structures 130 are exposed after the planarization process is complete. In some embodiments, the second CESL 160 and the second ILD may be similar to the first CESL and the first ILD in terms of composition and formation method thereof.

Afterwards, the dummy gate structures 130 are removed to form gate trenches in each pair of the gate spacers 140. The semiconductor layers 202 and 102 are then removed through the gate trenches, such that the semiconductor layers 204 and 104 are suspended over the substrate 100. In some embodiments, the semiconductor layers 202 and 102 may be removed using suitable etching process. In some embodiments, the semiconductor layers 202 and 102 can also be referred to as sacrificial layers. The semiconductor layers 102 and 202 can be replaced with metal gate structures.

Gate dielectric layers 174 and 274 are formed wrapping around the semiconductor layers 104 and 204, respectively. In some embodiments, the gate dielectric layers 174 and 274 may be formed using a same deposition process. In some embodiments, interfacial layers (not shown) may be formed over the semiconductor layers 104 and 204 prior to forming the gate dielectric layers 174 and 274.

Then, gate electrodes 276 are formed over the gate dielectric layers 274. The gate electrodes 1276 are then etched back, such that the remaining gate electrodes 276 are at the lower portion of the gate trenches. Accordingly, a first metal gate structure 170 and a second metal gate structure 270 are formed. In greater detail, the first metal gate structure 170 are formed in bottom portions of the gate trenches GT1, such that the first metal gate structures 170 may wrap around the respective semiconductor layers 102. In some embodiments, each of the first metal gate structures 170 may include the gate dielectric layer 174 and the gate electrode 176 over the gate dielectric layer 174. The first and second insulation layers 106, 108 can be vertically between the first metal gate structure 170 and the second metal gate structure 270.

In some embodiments, the interfacial layers may be made of oxide, such as aluminum oxide (Al₂O₃), silicon oxide (SiO₂), or the like. In some embodiments, the gate dielectric layers 174 and 274 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate electrodes 176 and 276 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s). In some embodiments, the gate electrodes 176 may include n-type work function metal layer, while the gate electrodes 276 may include p-type work function metal layer. As discussed previously with regard to FIGS. 9 and 10, the first metal gate structures 170 can include a gate length 170w along the first direction D1 different from a gate length 270w of the second metal gate structures 172 along the first direction D1. In other words, the first metal gate structure 170 extending a first width (e.g., the gate length 170w) from a first one of the inner spacers 146b to a second one of the inner spacers 146b. The second metal gate structure 270 extends a second width (e.g., the gate length 270w) from a first one of the inner spacers 146t to a second one of the inner spacers 146t. A ratio of the first width (e.g., the gate length 170w) to the width of the first one of the inner spacers 146b is different from a ratio of the second width (e.g., the gate length 270w) to a width of the first one of the inner spacers 146t. For example, the first metal gate structures 170 can include the gate length 170w greater than the gate length 270w of the second metal gate structures 270. Such diversity between top gate length (i.e., the second metal gate structures 270) and bottom gate length (i.e., the first metal gate structures 170) can be controlled and thus enables the flexibility of the device architecture.

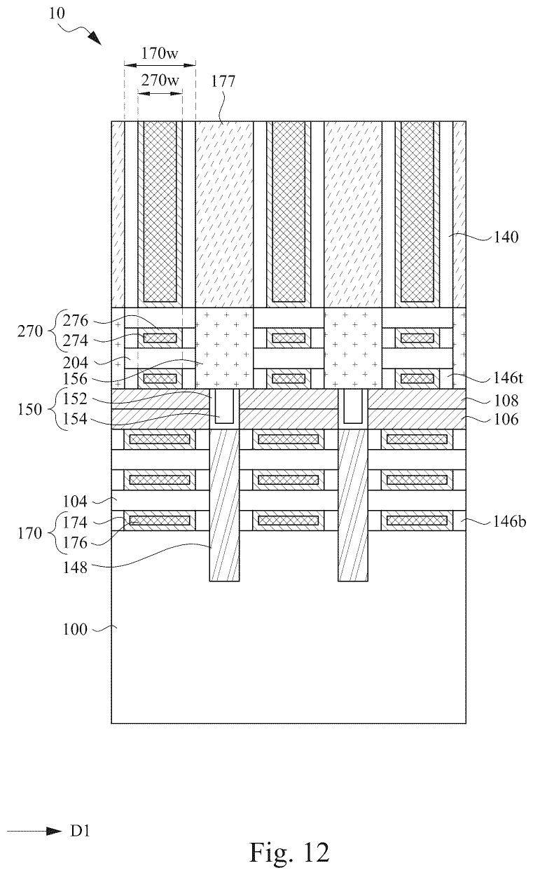

Reference is made to FIG. 12. After the metal gate structures 164 and 170 are formed, source/drain contacts 177 are formed in the isolation structures 158 and in contact with the second source/drain epitaxy structures 156, respectively. In some embodiments, the source/drain contacts 177 may be formed by, for example, etching the isolation structures 158 to form openings in the isolation structures 158 that expose the second source/drain epitaxy structures 156, filling the openings with conductive material(s), and then performing a planarization process, such as CMP, to remove excess conductive material(s). In some embodiments, each of the source/drain contacts 177 may include a diffusion barrier layer and a contact plug over the diffusion barrier layer. The diffusion barrier layer may include tantalum-based or titanium-based material, such as tantalum nitride (TaN), titanium nitride (TiN), titanium oxide (TiO), titanium (Ti), or the like. The contact plug may include tungsten (W), copper (Cu), aluminum (Al), ruthenium (Ru), cobalt (Co), molybdenum (Mo), nickel (Ni), or other suitable conductive material.

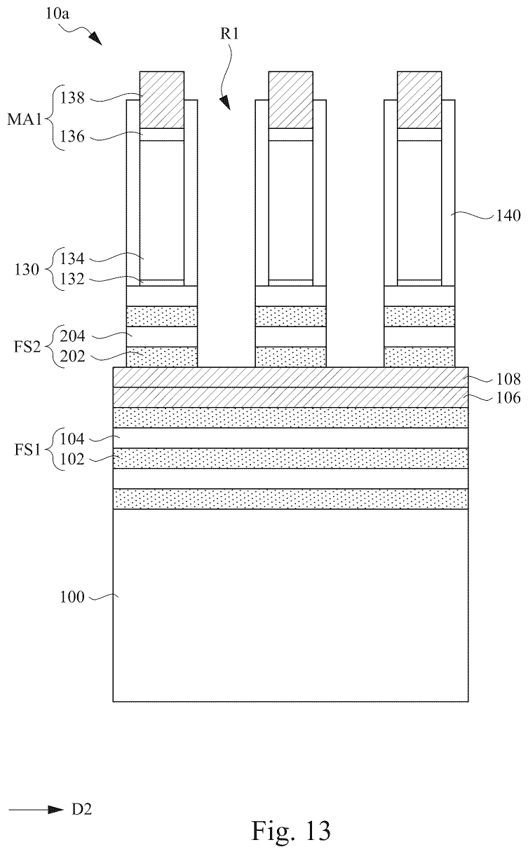

FIGS. 13-22 illustrate a method in various stages of forming a semiconductor device in accordance with some other embodiments of the present disclosure. In greater detail, FIGS. 12 to 22 illustrate a method for forming a detailed structure of the CFET 10a of FIG. 1. It is noted that FIGS. 13-22 include cross-sectional views the same as the cross-sectional view along line B-B of FIG. 1. It is noted that some elements discussed in FIGS. 13 to 22 may be similar to those described with respect to FIGS. 2A to 12, such elements are labeled the same and relevant details will not be repeated for brevity.

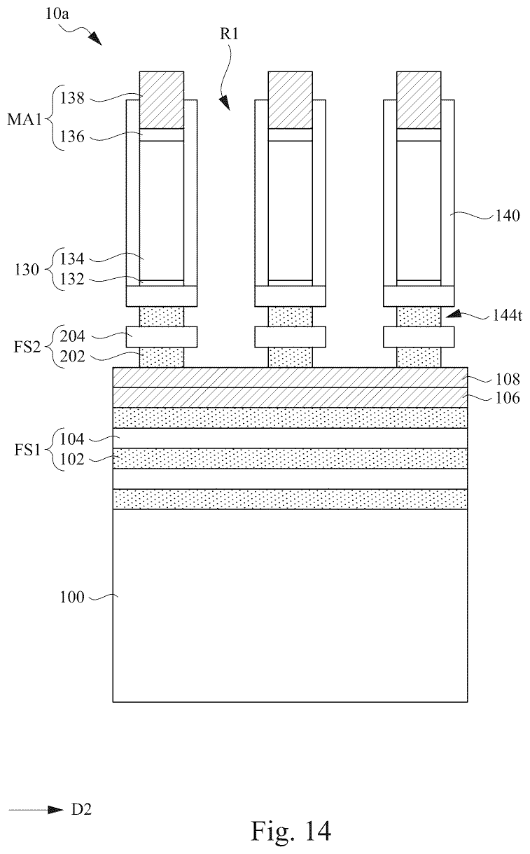

Reference is made to FIG. 13. Shown there is the CFET 10a. The CFET 10a is similar to the CFET 10 as discussed previously with regard to FIG. 6, and thus the description thereof is omitted herein. Reference is made to FIG. 14. The semiconductor layers 204 are laterally etched to form sidewall recesses 144t. The sidewalls may be etched using isotropic etching processes, such as wet etching or the like. In some embodiments, the second insulation layer 108 may include higher etch resistance to the etching process than the semiconductor layers 202, and thus the second insulation layer 108 may act as an etch stop layer during the etching process. As a result, the etching process may be stopped at the second insulation layer 108, and thus the underlying semiconductor layers 102 and 104 are protected by the second insulation layer 108 and may keep substantially intact after the etching process is complete.

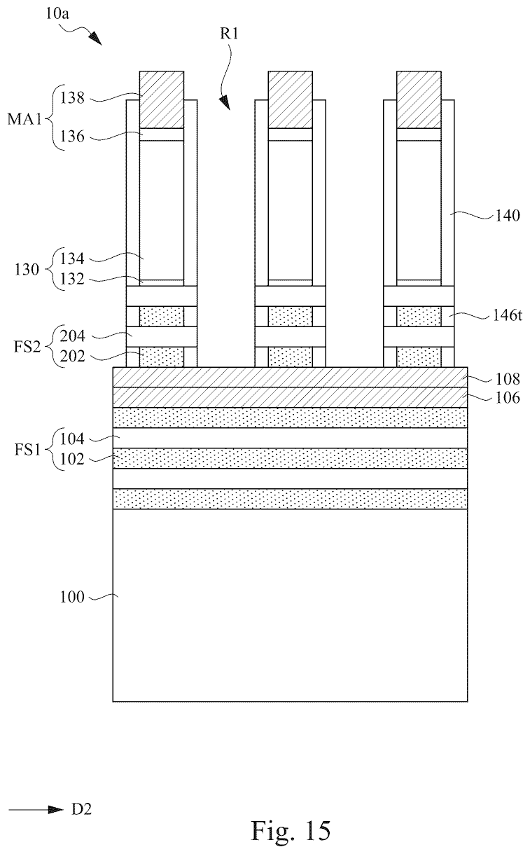

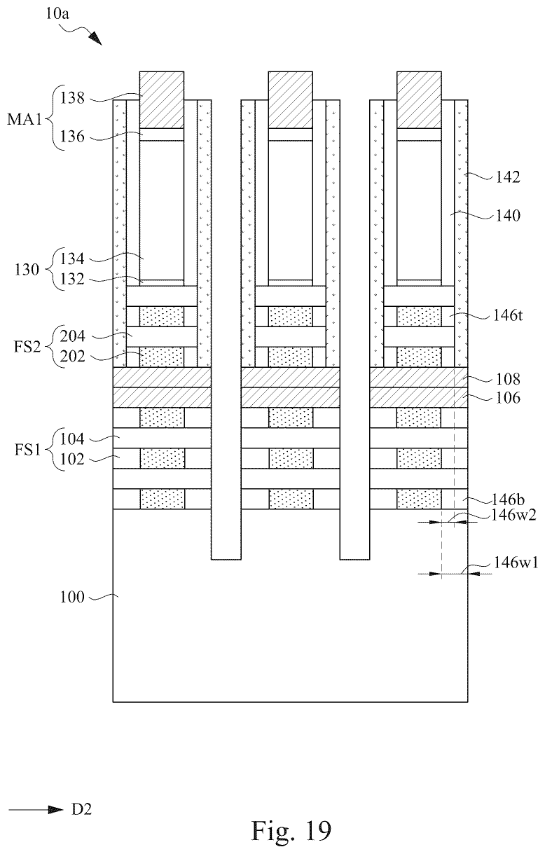

Reference is made to FIG. 15. Then, inner spacers 146t are formed in the sidewall recesses 144t on opposite ends of each of the semiconductor layers 202. In some embodiments, the inner spacers 146 may be formed by, for example, depositing an inner spacer layer blanket over the second insulating layer 108, filling the sidewall recesses 144t on opposite sides of the semiconductor layers 202, and then performing an anisotropic etching to remove portions of the inner spacer layer outside the sidewall recesses 144t, leaving the remaining portions of the inner spacer layer in the sidewall recesses 144t as the inner spacers 146t. The inner spacers 146t may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized. In some embodiments, because the inner spacers 146t and subsequently formed inner spacers (e.g., the inner spacers 146b in FIG. 19) are formed in different steps, the inner spacers 146t may include the width different from the width of the inner spacers 146b.

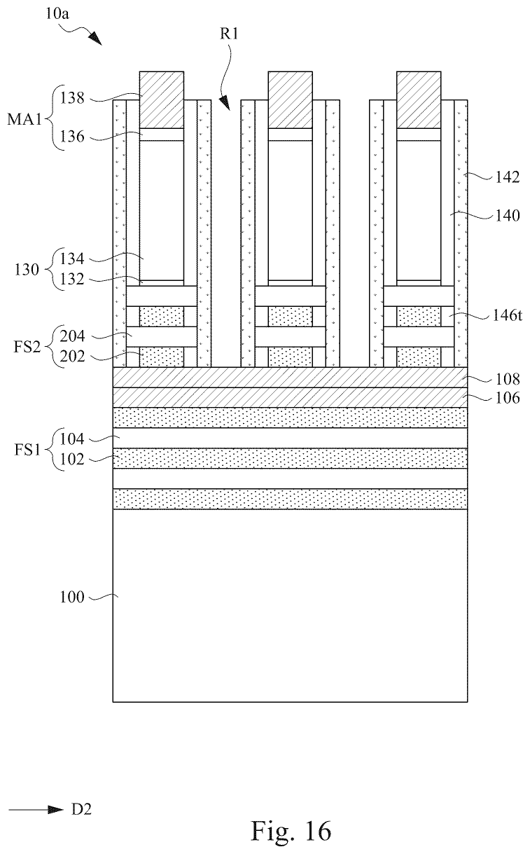

Reference is made to FIG. 16. Liners 142 are formed lining sidewall surfaces of the semiconductor layers 204, sidewall surfaces of the inner spacers 146t and sidewall surfaces of the gate spacers 140. Formation method and material of the liners 142 are discussed previously with regard to FIG. 7, and thus the description thereof is omitted herein. The liners 142 can protect the gate spacers 140, the semiconductor layers 204 and the inner spacers 146t from being damaged during a subsequent etching process.

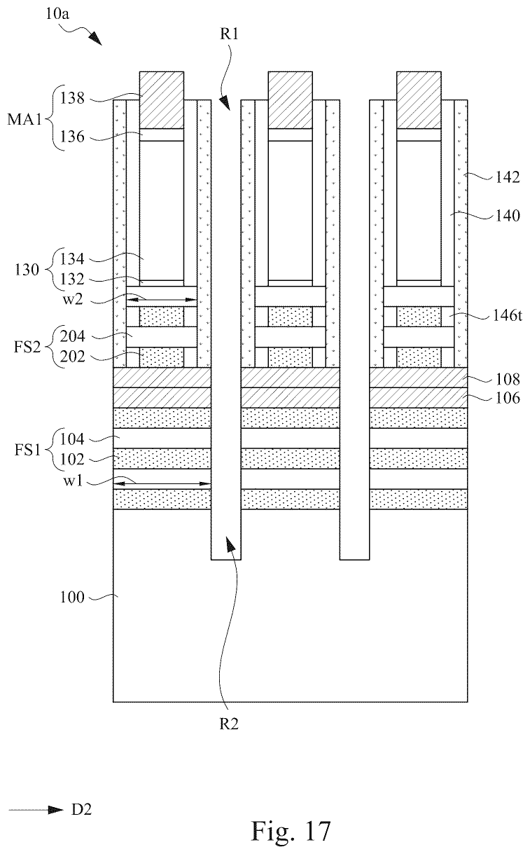

Reference is made to FIG. 17. Then, an etching process is performed, by using the liners 142, the gate spacers 140, and the patterned masks MA1 (or the dummy gate structures 130) as etch mask, to remove a portion of the second insulation layer 108, a portion of the first insulation layer 106 and portions of the first fin structure FS1. In greater detail, the etching process removes portions of the semiconductor layers 102 and 104, so as to form recesses R2 in the first fin structure FS1. Due to the presence of the liners 142, the first fin structure FS1 can include the width different from (e.g., greater than) the width of the second fin structure.

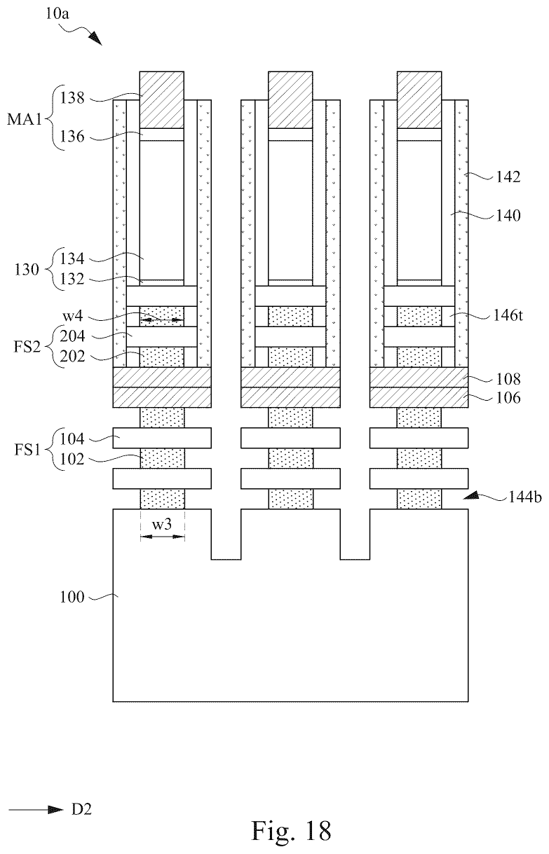

Reference is made to FIG. 18. The semiconductor layers 102 are laterally etched to form sidewall recesses 144b. Since subsequently formed inner spacers inherit space of the sidewall recesses 144, by controlling an etch amount of the semiconductor layers 102 during the etching process, the width of the inner spacers can be tuned. That is, the etch amount of the semiconductor layers 102 is in positive correlation of the thickness of the inner spacers, and as such, the diversity between the width of top inner spacers and the width of bottom inner spacers can be controlled. Therefore, the CFET 10a can have a top inner spacer width different from a bottom inner spacer width, thus enabling the flexibility of the device architecture.

In FIG. 18, after etching the semiconductor layers 102, the semiconductor layers 102 can have a width w3 along the first direction D1 substantially the same as a width w4 of the semiconductor layer 202 along the first direction D1.

Reference is made to FIG. 19. Then, inner spacers 146b may be formed in the sidewall recesses 144b on opposite ends of each of the semiconductor layers 102. Formation method and material of the inner spacers 146b can be similar to the inner spacers 146t as discussed previously with regard to FIG. 15. In some embodiments, the inner spacers 146 b can include a width 146w1 along the first direction different from a width 146w2 of the inner spacers 146t along the first direction. For example, the width 146w1 can be greater than the width 146w2.

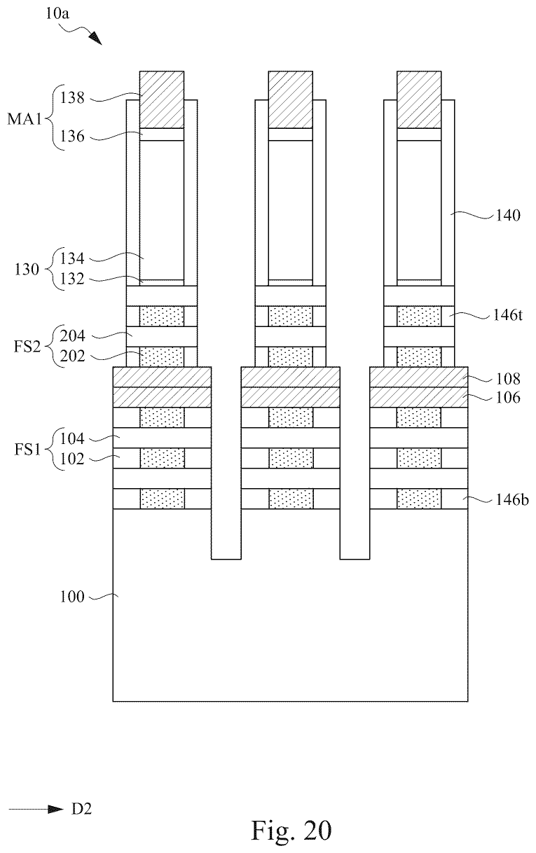

Reference is made to FIG. 20. The liners 142 are removed by using suitable etching process, such that sidewalls of the semiconductor layers 204 and sidewalls of the gate spacers 140 are exposed.

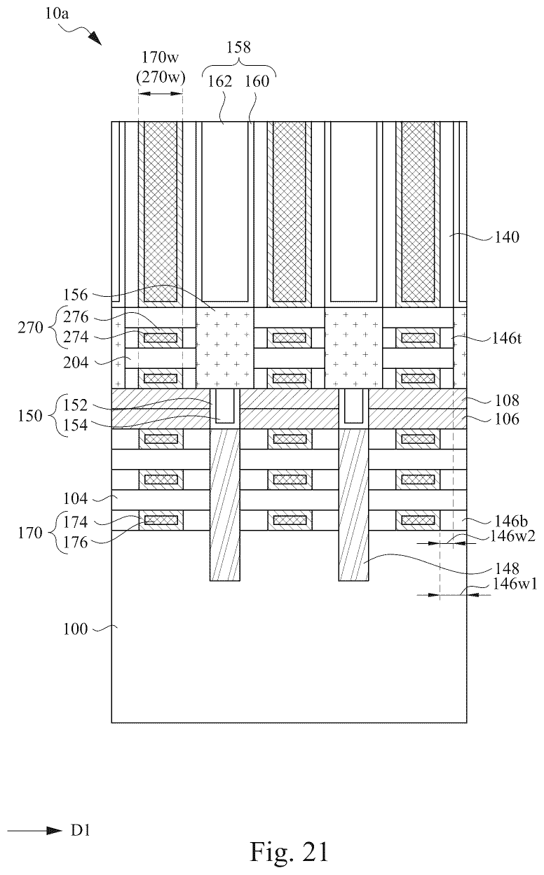

Reference is made to FIG. 21. First source/drain epitaxy structures 148 are formed over the substrate 100 and in contact with (or connected to) opposite ends of the semiconductor layers 104. The first source/drain epitaxy structures 148 may be formed by suitable deposition process, such as CVD, ALD or MBE. During the formation of the first source/drain epitaxy structures 148, the semiconductor layers 202 and 204 may be masked to prevent undesired epitaxial growth on the semiconductor layers 202 and 204. After the first source/drain epitaxy structures 148 are formed, the masks on the semiconductor layers 202 and 204 may then be removed. Then, isolation structures 150 are formed over the first source/drain epitaxy structures 148, respectively. The isolation structures can include a first contact etch stop layer (CESL) 152 and/or a first inter-layer dielectric (ILD) 154. Second source/drain epitaxy structures 156 are formed on opposite ends of each of the semiconductor layers 204. Isolation structures 158 are formed over the second source/drain epitaxy structures 156, respectively. Each of the isolation structures 158 may include a second contact etch stop layer (CESL) 160 and a second interlayer dielectric (ILD) 162 over the second CESL 160.

Afterwards, the dummy gate structures 130 are removed to form gate trenches in each pair of the gate spacers 140. The semiconductor layers 202 and 102 are then removed through the gate trenches, such that the semiconductor layers 204 and 104 are suspended over the substrate 100. In some embodiments, the semiconductor layers 202 and 102 may be removed using suitable etching process. In some embodiments, the semiconductor layers 202 and 102 can also be referred to as sacrificial layers.

Gate dielectric layers 174 and 274 are formed wrapping around the semiconductor layers 104 and 204, respectively. In some embodiments, interfacial layers (not shown) may be formed over the semiconductor layers 104 and 204 prior to forming the gate dielectric layers 174 and 274. Then, gate electrodes 276 are formed over the gate dielectric layers 274. The gate electrodes 276 are then etched back, such that the remaining gate electrodes 276 are at the lower portion of the gate trenches. Accordingly, a first metal gate structure 170 and a second metal gate structure 270 are formed. It is noted that elements discussed in FIG. 21 may be similar to those described with respect to FIG. 11 and such elements are labeled the same and relevant details will not be repeated for brevity. In some embodiments, the first metal gate structure 170 can include a gate length 170w substantially the same as a gate length 270w of the second metal gate structure 270.

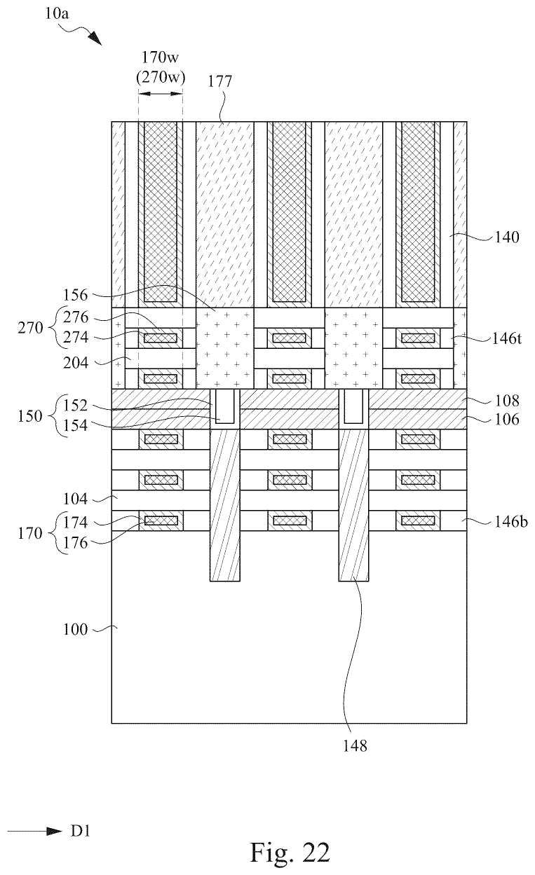

Reference is made to FIG. 22. After the metal gate structures 164 and 170 are formed, source/drain contacts 177 are formed in the isolation structures 158 and in contact with the second source/drain epitaxy structures 156, respectively.

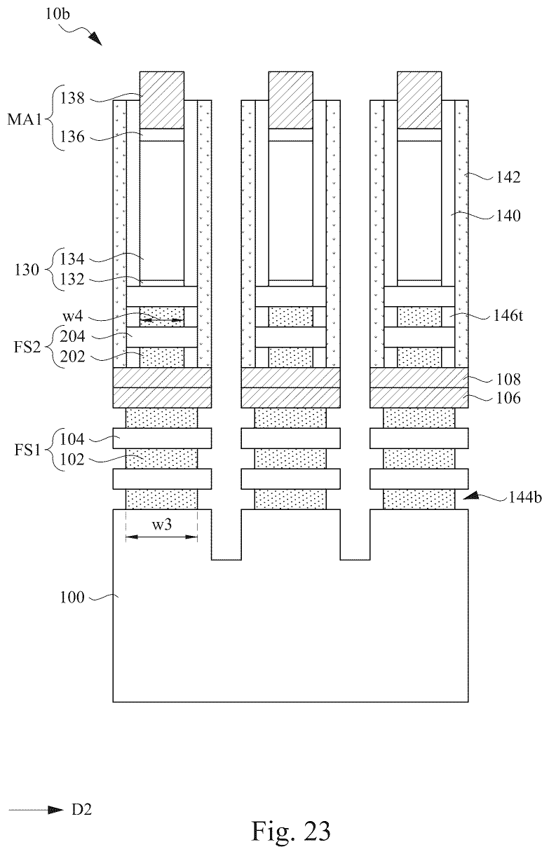

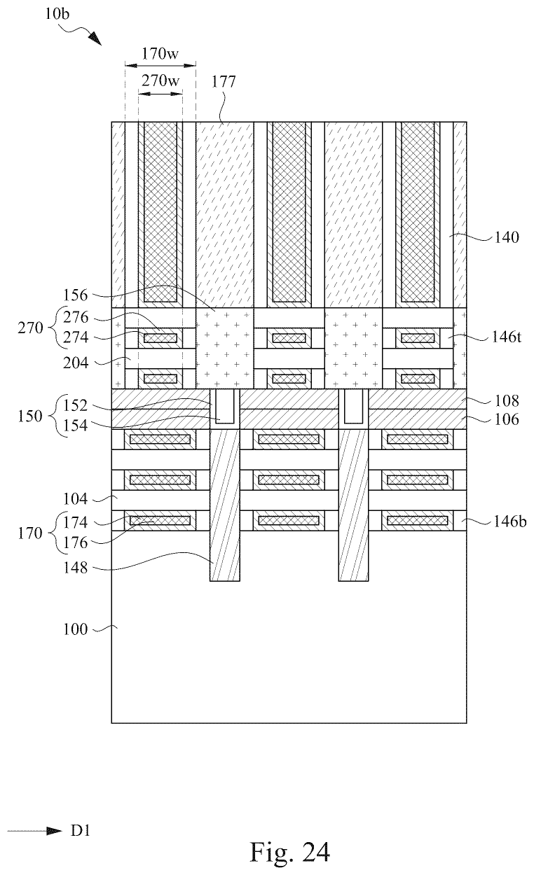

FIGS. 23-24 illustrate a method in various stages of forming a semiconductor device in accordance with some other embodiments of the present disclosure. In greater detail, FIGS. 23-24 illustrate a method for forming a detailed structure of the CFET 10b of FIG. 1. It is noted that FIGS. 23-24 include cross-sectional views the same as the cross-sectional view along line B-B of FIG. 1. It is noted that some elements discussed in FIGS. 23 and 24 may be similar to those described with respect to FIGS. 18 and 22, such elements are labeled the same and relevant details will not be repeated for brevity.

Reference is made to FIG. 23. The CFET 10b can be similar to the CFET 10a with regard to FIG. 18, except for the width w3 of the semiconductor layer 102 being greater than the width w4 of the semiconductor layer 202, and as such the resulting structure of the CFET 10b shown in FIG. 24 can include the first metal gate structure 170 having the gate length 170w greater than the gate length 270w of the second metal gate structure 270.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a CFET and a method for forming the CFET, which includes a first transistor and a second transistor above the first transistor. The first transistor and the second transistor include different conductivity types. In some embodiments, the first transistor is a p-type device and the second transistor is an n-type device. In other embodiments, the first transistor is an n-type device and the second transistor is a p-type device. By forming the liners on sidewalls of the semiconductor layers and the inner spacers for the second transistor after forming the source/drain recess, the etching amount of the semiconductor layers for the first transistor can be controlled. Therefore, the diversity between top gate length and bottom gate length can be controlled and thus enables the flexibility of the device architecture. Yet another advantage is that the diversity between the width of top inner spacers and the width of bottom inner spacers can also be controlled. Therefore, the CFET can have a top inner spacer width different from a bottom inner spacer width, thus enabling the flexibility of the device architecture.

In some embodiments, a method comprises the following steps. A first plurality of semiconductor nanostructures is formed over a substrate. A second plurality of semiconductor nanostructures is formed over the first plurality of semiconductor nanostructures. First source/drain regions are formed connected by the first plurality of semiconductor nanostructures. Second source/drain regions are formed connected by the second plurality of semiconductor nanostructures. First inner spacers are formed interposing the first plurality of semiconductor nanostructures. Second inner spacers are formed interposing the second plurality of semiconductor nanostructures. A gate structure is formed surrounding the first plurality of semiconductor nanostructures and the second plurality of semiconductor nanostructures, the gate structure being spaced apart from the first source/drain regions at least by the first inner spacers, and spaced apart from the second source/drain regions at least by the second inner spacers. Each of the first inner spacers has a width different from a width of each of the second inner spacers. In some embodiments, the width of each of the first inner spacers is greater than the width of each of the second inner spacers. In some embodiments, each of the first source/drain regions has a width different from a width of each of the second source/drain regions. In some embodiments, each of the first source/drain regions has a width smaller than a width of each of the second source/drain regions. In some embodiments, each of the first source/drain regions has a height different from a height of each of the second source/drain regions. In some embodiments, each of the first source/drain regions has a height greater than a height of each of the second source/drain regions. In some embodiments, the method further comprises forming gate spacers on opposite sidewalls of the gate structure, wherein each of the gate spacers has a width substantially the same as the width of each of the second inner spacers. In some embodiments, the method further comprises forming gate spacers on opposite sidewalls of the gate structure, wherein each of the gate spacers has a width different from the width of each of the first inner spacers. In some embodiments, each of the gate spacers has the width smaller than the width of each of the first inner spacers. In some embodiments, each of the first inner spacers and one of the first source/drain regions have an interface misaligned with an interface between each of the second inner spacers and one of the second source/drain regions.

In some embodiments, a method comprises the following steps. A first plurality of semiconductor nanostructures is formed over a substrate. A second plurality of semiconductor nanostructures is formed over the first plurality of semiconductor nanostructures. First source/drain regions are formed connected by the first plurality of semiconductor nanostructures. Second source/drain regions are formed connected by the second plurality of semiconductor nanostructures. First inner spacers are formed interposing the first plurality of semiconductor nanostructures. Second inner spacers are formed interposing the second plurality of semiconductor nanostructures. A gate structure is formed surrounding the first plurality of semiconductor nanostructures and the second plurality of semiconductor nanostructures, wherein the gate structure comprises a first portion laterally between the first inner spacers, and a second portion laterally between the second inner spacers, wherein the first portion of the gate structure has a width different from a width of the second portion of the gate structure. In some embodiments, the first portion of the gate structure has the width greater than the width of the second portion of the gate structure. In some embodiments, each of the first inner spacers has a width substantially the same as a width of each of the second inner spacers. In some embodiments, each of the first source/drain regions has a width different from a width of the second source/drain regions. In some embodiments, each of the first source/drain regions has a width smaller than a width of the second source/drain regions. In some embodiments, each of the first source/drain regions has a height different from a height of the second source/drain regions. In some embodiments, each of the first source/drain regions has the height greater than the height of the second source/drain regions.

In some embodiments, a semiconductor device comprises a substrate, first semiconductor layers stacked over the substrate and spaced apart from one another, second semiconductor layers stacked over the first semiconductor layers and spaced apart from one another, first inner spacers between the first semiconductor layers, second inner spacers between the second semiconductor layers, a first gate structure wrapping around the first semiconductor layers, the first gate structure extending a first width from a first one of the first inner spacers to a second one of the first inner spacers and a second gate structure wrapping around the second semiconductor layers. The second gate structure extends a second width from a first one of the second inner spacers to a second one of the second inner spacers. A ratio of the first width to a width of the first one of the first inner spacers is different from a ratio of the second width to a width of the first one of the second inner spacers. In some embodiments, the semiconductor device further comprises one or more insulation layers vertically between the first gate structure and the second gate structure. In some embodiments, the first width is greater than the second width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first plurality of semiconductor nanostructures over a substrate;
forming a second plurality of semiconductor nanostructures over the first plurality of semiconductor nanostructures;
forming first source/drain regions connected by the first plurality of semiconductor nanostructures;
forming second source/drain regions connected by the second plurality of semiconductor nanostructures;
forming first inner spacers interposing the first plurality of semiconductor nanostructures;
forming second inner spacers interposing the second plurality of semiconductor nanostructures; and
forming a gate structure surrounding the first plurality of semiconductor nanostructures and the second plurality of semiconductor nanostructures, the gate structure being spaced apart from the first source/drain regions at least by the first inner spacers, and spaced apart from the second source/drain regions at least by the second inner spacers,
wherein each of the first inner spacers has a width different from a width of each of the second inner spacers.

2. The method of claim 1, wherein the width of each of the first inner spacers is greater than the width of each of the second inner spacers.

3. The method of claim 1, wherein each of the first source/drain regions has a width different from a width of each of the second source/drain regions.

4. The method of claim 1, wherein each of the first source/drain regions has a width smaller than a width of each of the second source/drain regions.

5. The method of claim 1, wherein each of the first source/drain regions has a height different from a height of each of the second source/drain regions.

6. The method of claim 1, wherein each of the first source/drain regions has a height greater than a height of each of the second source/drain regions.

7. The method of claim 1, further comprising:
forming gate spacers on opposite sidewalls of the gate structure, wherein each of the gate spacers has a width substantially the same as the width of each of the second inner spacers.

8. The method of claim 1, further comprising:
forming gate spacers on opposite sidewalls of the gate structure, wherein each of the gate spacers has a width different from the width of each of the first inner spacers.

9. The method of claim 8, wherein each of the gate spacers has the width smaller than the width of each of the first inner spacers.

10. The method of claim 1, wherein each of the first inner spacers and one of the first source/drain regions have an interface misaligned with an interface between each of the second inner spacers and one of the second source/drain regions.

11. A method comprising:
forming a first plurality of semiconductor nanostructures over a substrate;
forming a second plurality of semiconductor nanostructures over the first plurality of semiconductor nanostructures;
forming first source/drain regions connected by the first plurality of semiconductor nanostructures;
forming second source/drain regions connected by the second plurality of semiconductor nanostructures;
forming first inner spacers interposing the first plurality of semiconductor nanostructures;
forming second inner spacers interposing the second plurality of semiconductor nanostructures; and
forming a gate structure surrounding the first plurality of semiconductor nanostructures and the second plurality of semiconductor nanostructures, wherein the gate structure comprises a first portion laterally between the first inner spacers, and a second portion laterally between the second inner spacers, wherein the first portion of the gate structure has a width different from a width of the second portion of the gate structure.

12. The method of claim 11, wherein the first portion of the gate structure has the width greater than the width of the second portion of the gate structure.

13. The method of claim 11, wherein each of the first inner spacers has a width substantially the same as a width of each of the second inner spacers.

14. The method of claim 11, wherein each of the first source/drain regions has a width different from a width of the second source/drain regions.

15. The method of claim 11, wherein each of the first source/drain regions has a width smaller than a width of the second source/drain regions.

16. The method of claim 11, wherein each of the first source/drain regions has a height different from a height of the second source/drain regions.

17. The method of claim 16, wherein each of the first source/drain regions has the height greater than the height of the second source/drain regions.

18. A semiconductor device, comprising:
a substrate;
first semiconductor layers stacked over the substrate and spaced apart from one another;
second semiconductor layers stacked over the first semiconductor layers and spaced apart from one another;
first inner spacers between the first semiconductor layers;
second inner spacers between the second semiconductor layers;
a first gate structure wrapping around the first semiconductor layers, the first gate structure extending a first width from a first one of the first inner spacers to a second one of the first inner spacers; and
a second gate structure wrapping around the second semiconductor layers, the second gate structure extending a second width from a first one of the second inner spacers to a second one of the second inner spacers,
wherein a ratio of the first width to a width of the first one of the first inner spacers is different from a ratio of the second width to a width of the first one of the second inner spacers.

19. The semiconductor device of claim 18, further comprising:
one or more insulation layers vertically between the first gate structure and the second gate structure.

20. The semiconductor device of claim 18, wherein the first width is greater than the second width.
